(19) United States
(12) Patent Application Publication
(10) Pub. No.: US 2026/0214952 A1
(43) Pub. Date: Jul. 23, 2026

(54) SEMICONDUCTOR DEVICE

(71) Applicant: TDK Corporation, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 19/569,418

(22) Filed: Mar. 17, 2026

Related U.S. Application Data
(63) Continuation of application No. PCT/JP2024/032178, filed on Sep. 9, 2024.

(30) Foreign Application Priority Data
Sep. 21, 2023 (JP) 2023-156321

(51) Int. Cl. H10D 62/10; H10D 8/60

(52) U.S. Cl. CPC H10D 62/112; H10D 8/60

(57) ABSTRACT

Disclosed herein is a semiconductor device that includes a semiconductor substrate, a drift layer formed on the semiconductor substrate, a first electrode in contact with the drift layer, and a second electrode in contact with the semiconductor substrate. The drift layer has: a plurality of outer peripheral trenches including a first outer peripheral trench formed so as to surround the first electrode in a plan view without overlapping the first electrode in a plan view and a second outer peripheral trench formed adjacent to the first outer peripheral trench and outside the first outer peripheral trench so as to surround the first outer peripheral trench in a plan view; and a first mesa region located between the first outer peripheral trench and the second outer peripheral trench. The first mesa region has a smaller width than the first outer peripheral trench.

### CROSS-REFERENCE TO RELATED APPLICATION

This application claims the benefit of Japanese Patent Application No. 2023-156321, filed on Sep. 21, 2023, the entire disclosure of which is incorporated by reference herein.

### BACKGROUND OF THE ART

### Field of the Art

The present disclosure relates to a semiconductor device and, more particularly, to a semiconductor device having a structure in which an outer peripheral trench is formed in a drift layer.

### Description of Related Art

JP 2023-010539 A discloses a semiconductor device including a first electrode layer in contact with the front surface of an n-type gallium oxide semiconductor layer, a second electrode layer in contact with the back surface of the n-type gallium oxide semiconductor layer, and a p-type nickel oxide semiconductor layer filled in a trench that is formed in the n-type gallium oxide semiconductor layer. In JP 2023-010539 A, a plurality of the trenches filled with the p-type nickel oxide semiconductor layer are provided, thereby suppressing concentration of the electric field generated when a reverse voltage is applied.

However, in the structure disclosed in JP 2023-010539 A, the effect of suppressing concentration of the electric field generated upon application of a reverse voltage at portions of the trench in the drift layer, such as the trench bottom, is insufficient.

### SUMMARY

A semiconductor device according to an aspect of the present disclosure includes: a semiconductor substrate; a drift layer formed on the semiconductor substrate; a first electrode in contact with the drift layer; and a second electrode in contact with the semiconductor substrate. The drift layer has: a plurality of outer peripheral trenches including a first outer peripheral trench formed so as to surround the first electrode in a plan view without overlapping the first electrode in a plan view and a second outer peripheral trench formed adjacent to the first outer peripheral trench and outside the first outer peripheral trench so as to surround the first outer peripheral trench in a plan view; and a first mesa region located between the first outer peripheral trench and the second outer peripheral trench. The first mesa region has a smaller width than the first outer peripheral trench.

### BRIEF DESCRIPTION OF THE DRAWINGS

The above features and advantages of the present disclosure will be more apparent from the following description of some embodiments taken in conjunction with the accompanying drawings, in which:

FIG. 1A is a schematic plan view illustrating the configuration of a semiconductor device 1 according to a first embodiment of the technology described herein;

FIG. 1B is a schematic cross-sectional view taken along the line A-A in FIG. 1A;

FIG. 2A is a schematic cross-sectional view for explaining the structure of the semiconductor device 1 according to a first modification;

FIG. 2B is a schematic cross-sectional view for explaining the structure of the semiconductor device 1 according to a second modification;

FIG. 2C is a schematic cross-sectional view for explaining the structure of the semiconductor device 1 according to a third modification;

FIG. 3A is a schematic cross-sectional view for explaining the structure of the semiconductor device 1 according to a fourth modification;

FIG. 3B is a schematic cross-sectional view for explaining the structure of the semiconductor device 1 according to a fifth modification;

FIG. 3C is a schematic cross-sectional view for explaining the structure of the semiconductor device 1 according to a sixth modification;

FIG. 4A is a schematic cross-sectional view for explaining the structure of the semiconductor device 1 according to a seventh modification;

FIG. 4B is a schematic cross-sectional view for explaining the structure of the semiconductor device 1 according to an eighth modification;

FIG. 5A is a schematic plan view illustrating the configuration of a semiconductor device 2 according to a second embodiment of the technology described herein;

FIG. 5B is a schematic cross-sectional view taken along the line A-A in FIG. 5A;

FIG. 6 is a schematic cross-sectional view for explaining the structure of the semiconductor device 2 according to a first modification;

FIG. 7 is a schematic cross-sectional view for explaining the structure of the semiconductor device 2 according to a second modification;

FIG. 8 is a schematic cross-sectional view for explaining the structure of the semiconductor device 2 according to a third modification;

FIG. 9 is a schematic cross-sectional view for explaining the structure of the semiconductor device 2 according to a fourth modification;

FIG. 10 is a schematic cross-sectional view for explaining the structure of the semiconductor device 2 according to a fifth modification;

FIG. 11A is a schematic plan view illustrating the configuration of a semiconductor device 3 according to a third embodiment of the technology described herein;

FIG. 11B is a schematic cross-sectional view taken along the line A-A in FIG. 11A; and

FIG. 12 is a schematic cross-sectional view for explaining the structure of the semiconductor device 3 according to a modification.

### DETAILED DESCRIPTION OF THE EMBODIMENTS

The present disclosure describes a technology for effectively suppressing concentration of the electric field generated upon application of a reverse voltage in a semiconductor device having a structure in which outer peripheral trenches are formed in a drift layer.

Hereinafter, some embodiments of the technology described herein will be described in detail with reference to the accompanying drawings.

### First Embodiment

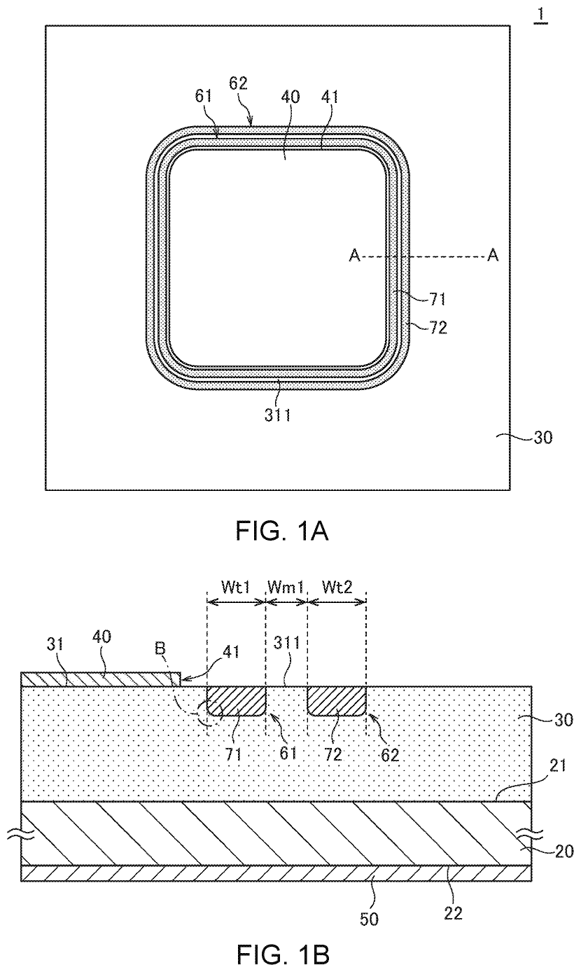

FIG. 1A is a schematic plan view illustrating the configuration of a semiconductor device 1 according to a first embodiment of the technology described herein. FIG. 1B is a schematic cross-sectional view taken along the line A-A in FIG. 1A.

The semiconductor device 1 illustrated in FIGS. 1A and 1B is a Schottky barrier diode, and includes a semiconductor substrate 20 and a drift layer 30, both of which are formed of gallium oxide (β-Ga₂O₃). Silicon (Si) or tin (Sn) is introduced into the semiconductor substrate 20 and the drift layer 30 as an n-type dopant. The dopant concentration is higher in the semiconductor substrate 20 than in the drift layer 30, whereby the semiconductor substrate 20 functions as an n⁺ layer, and the drift layer 30 functions as an n⁻ layer. For example, the semiconductor substrate 20 has a dopant concentration of 1×10¹⁸ cm⁻³, and the drift layer 30 has a dopant concentration of 1×10¹⁶ cm⁻³.

The semiconductor substrate 20 is obtained by slicing a bulk crystal formed by a melt-growth method, and has a thickness of about 250 μm. Although the planar size of the semiconductor substrate 20 is not particularly limited, it is generally determined according to the amount of current that flows through the device. When the maximum amount of forward current is about 20 A, the planar size of the semiconductor substrate 20 may be about 2.4 mm×2.4 mm in a plan view.

The semiconductor substrate 20 has a top surface 21, which is located on the upper side when the device is mounted, and a back surface 22, which is located on the lower side when the device is mounted. The drift layer 30 is formed on the entire top surface 21. The drift layer 30 is a thin film obtained by epitaxially growing gallium oxide on the top surface 21 by a reactive sputtering method, a PLD method, an MBE method, an MOCVD method, an HVPE method, or the like. Although the film thickness of the drift layer 30 is not particularly limited, it is generally determined according to the reverse breakdown voltage of the device. To ensure a breakdown voltage of about 600 V, the film thickness of the drift layer 30 may be set to about 15 μm, for example.

An anode electrode 40, which is brought into Schottky contact with the drift layer 30, is formed on the top surface 31 of the drift layer 30. The anode electrode 40 functions as a first electrode of the semiconductor device 1. The anode electrode 40 is formed of metal such as platinum (Pt), palladium (Pd), gold (Au), nickel (Ni), molybdenum (Mo), or copper (Cu). The anode electrode 40 may have a multilayer structure of different metal films, such as Pt/Au, Pt/Al, Pd/Au, Pd/Al, Pt/Ti/Au, or Pd/Ti/Au. On the other hand, there is formed, on the back surface 22 of the semiconductor substrate 20, a cathode electrode 50, which is brought into ohmic contact with the semiconductor substrate 20. The cathode electrode 50 functions as a second electrode of the semiconductor device 1. The cathode electrode 50 is formed of metal such as titanium (Ti). The cathode electrode 50 may have a multilayer structure of different metal films, such as Ti/Au or Ti/Al. In this case, Ti is in contact with the semiconductor substrate 20.

In the present embodiment, outer peripheral trenches 61 and 62 are formed in the drift layer 30. The outer peripheral trench 61 is provided so as to surround the anode electrode 40 in a plan view without overlapping the anode electrode 40. In other words, the outer peripheral trench 61 is provided further outside than an outer edge 41 of the anode electrode 40. The outer peripheral trench 62 is formed outside the outer peripheral trench 61 so as to surround the outer peripheral trench 61 in a plan view. The outer peripheral trenches 61 and 62 are adjacent to each other. The outer peripheral trenches 61 and 62 are filled with p-type semiconductor members 71 and 72, respectively, having a conductivity type opposite to that of the drift layer 30. Each of the p-type semiconductor members 71 and 72 forms a pn junction with the drift layer 30. Examples of the materials for the p-type semiconductor members 71 and 72 include Si, GaAs, GaN, SiC, Ge, ZnSe, CdS, InP, SiGe, AlN, BN, AlGaN, NiO, Cu₂O, Ir₂O₃, and Ag₂O.

As illustrated in FIG. 1B, the p-type semiconductor member 72 filled in the outer peripheral trenches 61 and 62 is not in contact with the anode electrode 40.

The portion of the top surface 31 of the drift layer 30 that is located between the outer peripheral trenches 61 and 62 constitutes a mesa region 311. The mesa region 311 is not in contact with the anode electrode 40. Assuming that the width of the outer peripheral trench 61 is Wt1, the width of the outer peripheral trench 62 is Wt2, and the width of the mesa region 311 is Wm1, the relationship Wm1<Wt1=Wt2 holds in the example illustrated in FIG. 1B. That is, the mesa region 311 has a smaller width than the outer peripheral trench 61. The widths Wt1 and Wt2 of the outer peripheral trenches 61 and 62 need not be the same. For example, the width Wt2 of the outer peripheral trench 62 may be smaller than the width Wt1 of the outer peripheral trench 61.

Thus, when a reverse voltage is applied to the semiconductor device 1, the potential difference between the outer peripheral trenches 61 and 62 is small. Thus, the electric field applied to the outer peripheral trench 61 is dispersed over a wide range, resulting in a gentle electric field gradient. As a result, the strength of the electric field applied to the bottom of the outer peripheral trench 61, which is denoted by reference sign B in FIG. 1B, is reduced, thereby increasing the reliability of the semiconductor device 1.

For example, when the thickness of the drift layer 30 is 15 μm, the depths of the outer peripheral trenches 61 and 62 are 2 μm, the p-type semiconductor members 71 and 72 are formed of NiO, the anode electrode 40 is formed of Ni, and the cathode electrode 50 is formed of a laminated Ti/Au film, the electric field strength applied to the bottom (denoted by B) of the outer peripheral trench 61 upon application of a reverse voltage of 2000 V is as follows: when Wt1=Wt2=Wm1=3 μm, the electric field strength is 4.7 MV/cm, whereas when Wt1=Wt2=4 μm and Wm1=3 μm, the electric field strength is reduced to 4.5 MV/cm.

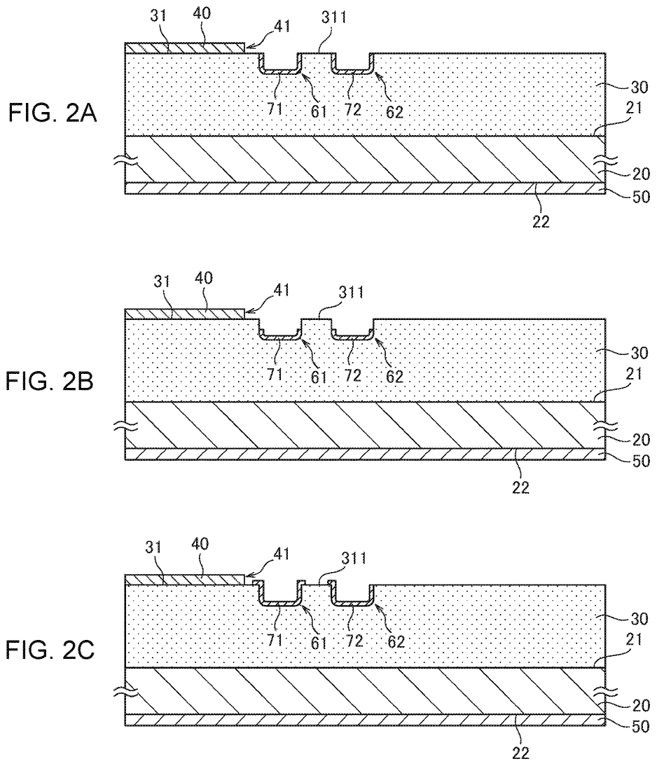

FIG. 2A is a schematic cross-sectional view for explaining the structure of the semiconductor device 1 according to a first modification. The first modification illustrated in FIG. 2A differs from the semiconductor device 1 illustrated in FIG. 1B in that the p-type semiconductor members 71 and 72 are not completely filled in the outer peripheral trenches 61 and 62, respectively, but are formed only on the inner walls of the outer peripheral trenches 61 and 62. Even with such a structure, the same effects as those of the semiconductor device 1 illustrated in FIGS. 1A and 1B can be obtained.

FIG. 2B is a schematic cross-sectional view for explaining the structure of the semiconductor device 1 according to a second modification. The second modification illustrated in FIG. 2B differs from the semiconductor device 1 illustrated in FIG. 1B in that, among the inner walls of the peripheral trenches 61 and 62, p-type semiconductor members 71 and 72 are selectively provided on the bottom surfaces and on the corners that are the boundaries between the bottom surfaces and the side surfaces, respectively. Even with such a structure, the same effects as those of the semiconductor device 1 illustrated in FIGS. 1A and 1B can be obtained.

FIG. 2C is a schematic cross-sectional view for explaining the structure of the semiconductor device 1 according to a third modification. The third modification illustrated in FIG. 2C differs from the semiconductor device 1 illustrated in FIG. 2A in that the inner walls of the outer peripheral trenches 61 and 62, as well as the portions of the drift layer top surface 31 located adjacent to those walls, are covered with the p-type semiconductor members 71 and 72. Even with such a structure, the same effects as those of the semiconductor device 1 illustrated in FIGS. 1A and 1B can be obtained.

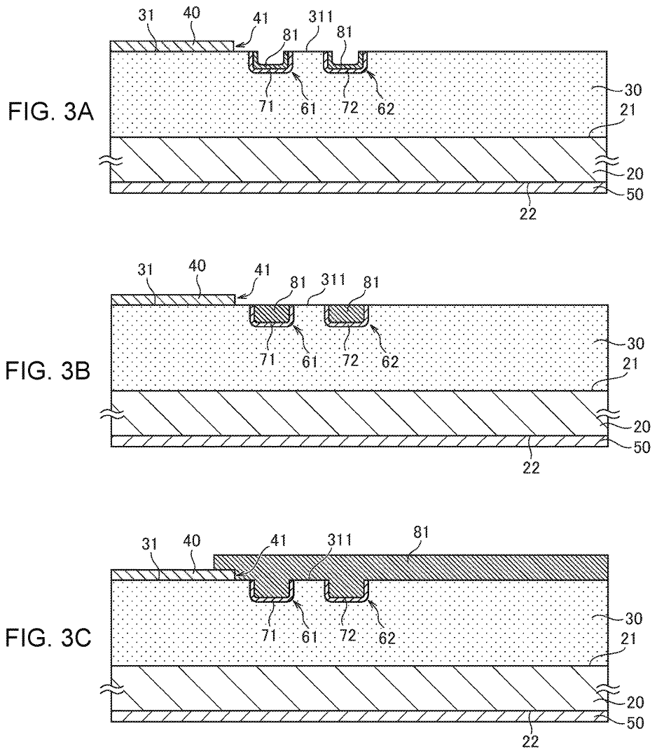

FIG. 3A is a schematic cross-sectional view for explaining the structure of the semiconductor device 1 according to a fourth modification. The fourth modification illustrated in FIG. 3A differs from the first modification of the semiconductor device 1 illustrated in FIG. 2A in that the surfaces of the p-type semiconductor members 71 and 72 are covered with an insulating film 81. Even with such a structure, the same effects as those of the semiconductor device 1 illustrated in FIGS. 1A and 1B can be obtained.

FIG. 3B is a schematic cross-sectional view for explaining the structure of the semiconductor device 1 according to a fifth modification. The fifth modification illustrated in FIG. 3B differs from the fourth modification of the semiconductor device 1 illustrated in FIG. 3A in that the outer peripheral trenches 61 and 62 are filled with the insulating film 81 via the p-type semiconductor members 71 and 72, respectively. Even with such a structure, the same effects as those of the semiconductor device 1 illustrated in FIGS. 1A and 1B can be obtained.

FIG. 3C is a schematic cross-sectional view for explaining the structure of the semiconductor device 1 according to a sixth modification. The sixth modification illustrated in FIG. 3C differs from the fifth modification of the semiconductor device 1 illustrated in FIG. 3B in that the top surface 31 of the drift layer 30 exposed from the anode electrode 40 and the outer peripheral portion of the anode electrode 40 are covered with the insulating film 81. Even with such a structure, the same effects as those of the semiconductor device 1 illustrated in FIGS. 1A and 1B can be obtained.

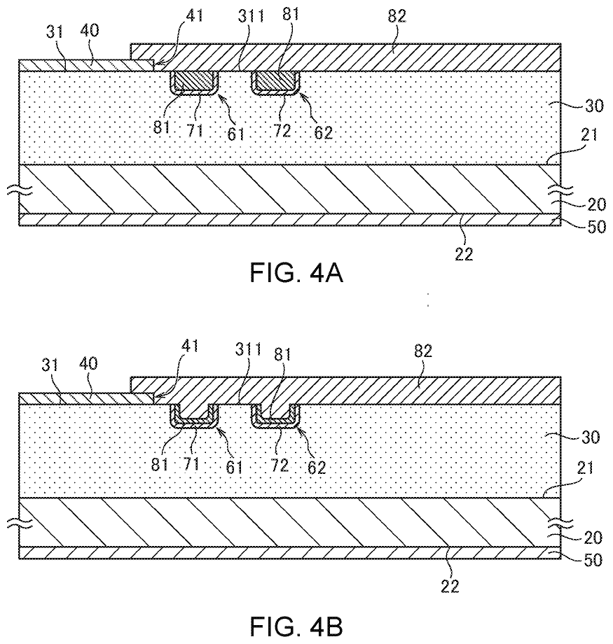

FIG. 4A is a schematic cross-sectional view for explaining the structure of the semiconductor device 1 according to a seventh modification. The seventh modification illustrated in FIG. 4A differs from the fifth modification of the semiconductor device 1 illustrated in FIG. 3B in that the top surface 31 of the drift layer 30 exposed from the anode electrode 40 and the outer peripheral portion of the anode electrode 40 are covered with an insulating film 82 different from the insulating film 81. Even with such a structure, the same effects as those of the semiconductor device 1 illustrated in FIGS. 1A and 1B can be obtained.

FIG. 4B is a schematic cross-sectional view for explaining the structure of the semiconductor device 1 according to an eighth modification. The eighth modification illustrated in FIG. 4B differs from the fourth modification of the semiconductor device 1 illustrated in FIG. 3A in that the top surface 31 of the drift layer 30 exposed from the anode electrode 40, the outer peripheral portion of the anode electrode 40, and the inside of the outer peripheral trench 62 are covered with the insulating film 82 different from the insulating film 81. Even with such a structure, the same effects as those of the semiconductor device 1 illustrated in FIGS. 1A and 1B can be obtained.

### Second Embodiment

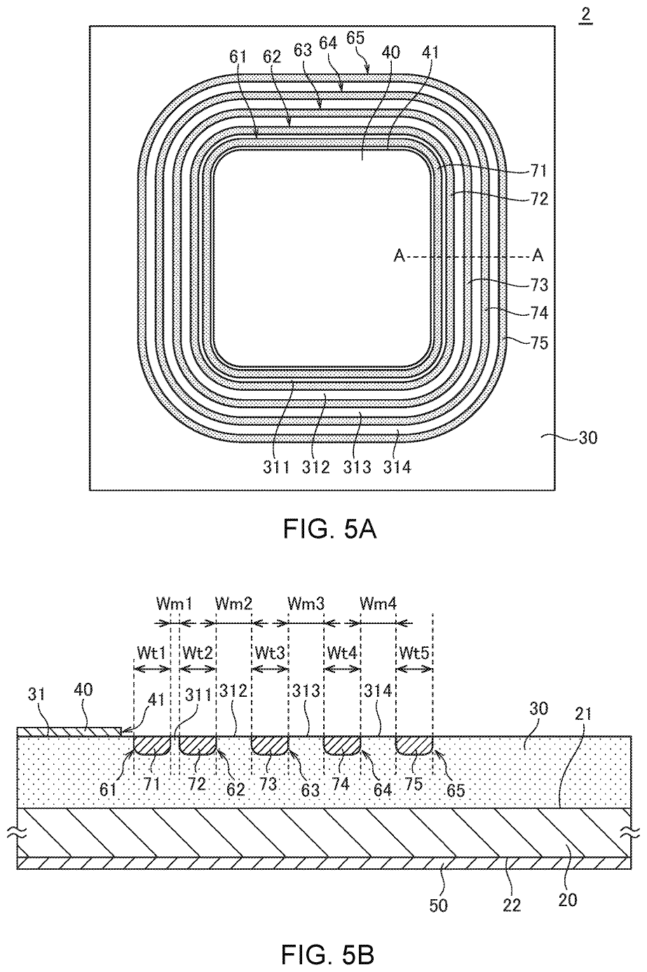

FIG. 5A is a schematic plan view illustrating the configuration of a semiconductor device 2 according to a second embodiment of the technology described herein. FIG. 5B is a schematic cross-sectional view taken along the line A-A in FIG. 5A.

The semiconductor device 2 according to the second embodiment differs from the semiconductor device 1 according to the first embodiment in that outer peripheral trenches 63 to 65 are additionally formed in the drift layer 30 and filled with p-type semiconductor members 73 to 75. Other basic configurations are the same as those of the semiconductor device 1 according to the first embodiment, so the same reference numerals are given to the same elements, and overlapping description will be omitted.

The outer peripheral trench 63 is formed outside the outer peripheral trench 62 so as to surround the outer peripheral trench 62 in a plan view. The outer peripheral trench 64 is formed outside the outer peripheral trench 63 so as to surround the outer peripheral trench 63 in a plan view. The outer peripheral trench 65 is formed outside the outer peripheral trench 64 so as to surround the outer peripheral trench 64 in a plan view. The outer peripheral trench 65 is provided as the outermost trench located at the outermost periphery. The p-type semiconductor members 71 to 75 filled in the outer peripheral trenches 61 to 65, respectively, are not in contact with the anode electrode 40.

The portion of the top surface 31 of the drift layer 30 that is located between the outer peripheral trenches 62 and 63 constitutes a mesa region 312. The portion of the top surface 31 of the drift layer 30 that is located between the outer peripheral trenches 63 and 64 constitutes a mesa region 313. The portion of the top surface 31 of the drift layer 30 that is located between the outer peripheral trenches 64 and 65 constitutes a mesa region 314. Like the mesa region 311, the mesa regions 312 to 314 are not in contact with the anode electrode 40.

Assuming that the widths of the outer peripheral trenches 61 to 65 are Wt1 to Wt5, respectively, and the widths of the mesa regions 311 to 314 are Wm1 to Wm4, respectively, the relationships Wm1<Wt1=Wt2=Wt3=Wt4=Wt5, and Wm1<Wm2=Wm3=Wm4 hold in the example illustrated in FIGS. 5A and 5B. That is, the mesa region 311 has a smaller width than the outer peripheral trenches 61 to 65, and also has a smaller width than the mesa region 314. In the examples of FIGS. 5A and 5B, among two mesa regions that are adjacent to each other, the mesa region located on the outer peripheral side has a larger width than the mesa region located on the inner peripheral side or has a width equal to that of the mesa region located on the inner peripheral side. That is, among two adjacent mesa regions, the mesa region located on the outer peripheral side has a width equal to or larger than that of the mesa region located on the inner peripheral side.

When three or more outer peripheral trenches are thus formed in the drift layer 30, the electric field gradient upon application of a reverse voltage to the semiconductor device 2 becomes gentler, thereby reducing the maximum electric field applied to the drift layer 30. In addition, since the width of the mesa region 311 is smaller than those of the other mesa regions 312 to 314, the potential difference between the outer peripheral trenches 61 and 62 decreases, which also reduces the maximum electric field applied to the drift layer 30. This increases the reliability of the semiconductor device 2.

For example, in the semiconductor device 1 according to the first embodiment, when the thickness of the drift layer 30 is 15 μm, the depths of the outer peripheral trenches 61 and 62 are 2 μm, the p-type semiconductor members 71 and 72 are formed of NiO, the anode electrode 40 is formed of Ni, and the cathode electrode 50 is formed of a laminated Ti/Au film, the maximum electric field strength applied to the drift layer 30 upon application of a reverse voltage of 2000 V is as follows: when Wt1=Wt2=4 μm, and Wm1=3 μm, the maximum electric field strength is 6.7 MV/cm, whereas, in the semiconductor device 2 according to the second embodiment, when the thickness of the drift layer 30 is 15 μm, the depths of the outer peripheral trenches 61 to 65 are 2 μm, the p-type semiconductor members 71 to 75 are formed of NiO, the anode electrode 40 is formed of Ni, and the cathode electrode 50 is formed of a laminated Ti/Au film, the maximum electric field strength applied to the drift layer 30 upon application of a reverse voltage of 2000 V is as follows: when Wt1=Wt2=Wt3=Wt4=Wt5=4 μm, Wm1=1 μm, and Wm2=WM3=Wm4=4 μm, the maximum electric field strength is reduced to 6.3 MV/cm.

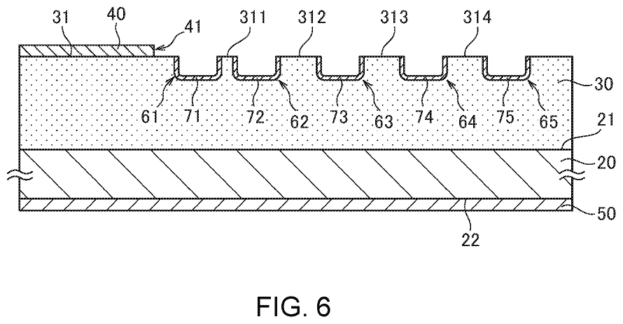

FIG. 6 is a schematic cross-sectional view for explaining the structure of the semiconductor device 2 according to a first modification. The first modification illustrated in FIG. 6 differs from the semiconductor device 2 illustrated in FIG. 5B in that the p-type semiconductor members 71 to 75 are not completely filled in the outer peripheral trenches 61 to 65, respectively, but are formed only on the inner walls of the outer peripheral trenches 61 to 65, as in the first modification of the semiconductor device 1 illustrated in FIG. 2A. Even with such a structure, the same effects as those of the semiconductor device 2 illustrated in FIGS. 5A and 5B can be obtained.

Further, in the semiconductor device 2 according to the second embodiment, the p-type semiconductor members 71 to 75 may be provided only on the bottom surfaces and on the bottom-sidewall corners of the inner walls of the outer peripheral trenches 61 to 65 as in the third modification of the semiconductor device 1 illustrated in FIG. 2B, and the inner walls of the outer peripheral trenches 61 to 65, as well as the portions of the top surface 31 of the drift layer 30 located adjacent to those inner walls, are covered with the p-type semiconductor members 71 to 75 as in the third modification of the semiconductor device 1 illustrated in FIG. 2C.

Further, in the semiconductor device 2 according to the second embodiment, the surfaces of the p-type semiconductor members 71 to 75 may be covered with the insulating film 81 as in the fourth modification of the semiconductor device 1 illustrated in FIG. 3A, the outer peripheral trenches 61 to 65 may be filled with the insulating film 81 via the p-type semiconductor members 71 to 75, respectively, as in the fifth modification of the semiconductor device 1 illustrated in FIG. 3B, and the top surface 31 of the drift layer 30 exposed from the anode electrode 40 and the outer peripheral portion of the anode electrode 40 may be covered with the insulating film 81 as in the sixth modification of the semiconductor device 1 illustrated in FIG. 3C.

Further, in the semiconductor device 2 according to the second embodiment, the outer peripheral trenches 61 to 65 may be filled with the insulating film 81 via the p-type semiconductor members 71 to 75, respectively, and the top surface 31 of the drift layer 30 exposed from the anode electrode 40 and the outer peripheral portion of the anode electrode 40 may be covered with the insulating film 82 different from the insulating film 81 as in the seventh modification of the semiconductor device 1 illustrated in FIG. 4A, and the surfaces of the p-type semiconductor members 71 to 75 may be covered with the insulating film 81, and the top surface 31 of the drift layer 30 exposed from the anode electrode 40, the outer peripheral portion of the anode electrode 40, and the inside of each of the outer peripheral trenches 62 to 65 may be covered with the insulating film 82 different from the insulating film 81 as in the eighth modification of the semiconductor device 1 illustrated in FIG. 4B.

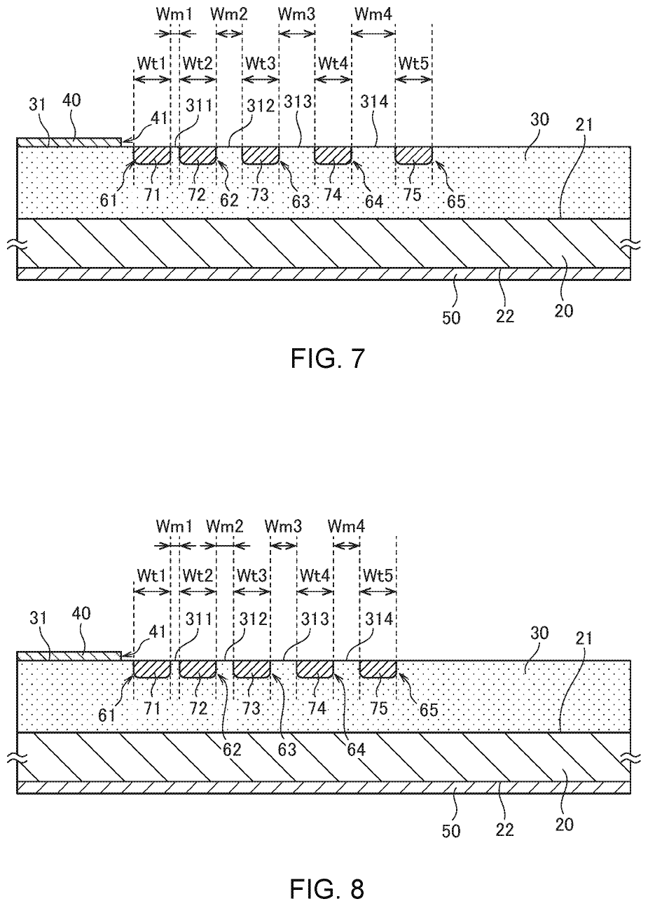

FIG. 7 is a schematic cross-sectional view for explaining the structure of the semiconductor device 2 according to a second modification. The second modification illustrated in FIG. 7 differs from the semiconductor device 2 illustrated in FIG. 5B in that the relationship Wm1<Wm2<Wm3<Wm4 holds. That is, among two mesa regions that are adjacent to each other, the mesa region located on the outer peripheral side has a width larger than the width of the mesa region located on the inner peripheral side. As a result, the potential difference between two adjacent outer peripheral trenches decreases toward the inner peripheral side, thereby further reducing the maximum electric field applied to the drift layer 30.

For example, when the thickness of the drift layer 30 is 15 μm, the depths of the outer peripheral trenches 61 to 65 are 2 μm, the p-type semiconductor members 71 to 75 are formed of NiO, the anode electrode 40 is formed of Ni, and the cathode electrode 50 is formed of a laminated Ti/Au film, the maximum electric field strength applied to the drift layer 30 upon application of a reverse voltage of 2000 V is as follows: when Wt1=Wt2=Wt3=Wt4=Wt5=4 μm, Wm1=1 μm, Wm2=3 μm, Wm3=4 μm, and Wm4=5 μm, the maximum electric field strength is reduced to 5.6 MV/cm. In the above example, the width of the outermost mesa region 314 is larger than those of the outer peripheral trenches 61 to 65. The width of the second outermost mesa region 313 is equal to those of the outer peripheral trenches 61 to 65. As described above, the innermost mesa region 311 may be designed to have a smaller width than that of the outer peripheral trenches 61 to 65, and the outermost mesa region 314 may be designed to have a larger width than that of the outer peripheral trenches 61 to 65.

FIG. 8 is a schematic cross-sectional view for explaining the structure of the semiconductor device 2 according to a third modification. The third modification illustrated in FIG. 8 differs from the second modification of the semiconductor device 2 illustrated in FIG. 7 in that the relationship Wm1<Wm2<Wm3≤Wm4<Wt4 holds. That is, the width of the outermost mesa region 314 is smaller than that of the outer peripheral trench 64 which is adjacent to the outer peripheral trench 65 serving as the outermost trench. This further reduces the maximum electric field applied to the drift layer 30. Further, in the example illustrated in FIG. 8, among two mesa regions that are adjacent to each other, the mesa region located on the outer peripheral side has a width equal to or larger than the width of the mesa region located on the inner peripheral side.

For example, when the thickness of the drift layer 30 is 15 μm, the depths of the outer peripheral trenches 61 to 65 are 2 μm, the p-type semiconductor members 71 to 75 are formed of NiO, the anode electrode 40 is formed of Ni, and the cathode electrode 50 is formed of a laminated Ti/Au film, the maximum electric field strength applied to the drift layer 30 upon application of a reverse voltage of 2000 V is as follows: when Wt1=Wt2=Wt3=Wt4=Wt5=4 μm, Wm1=1 μm, Wm2=2 μm, and Wm3=Wm4=3 μm, the maximum electric field strength is reduced to 5.3 MV/cm.

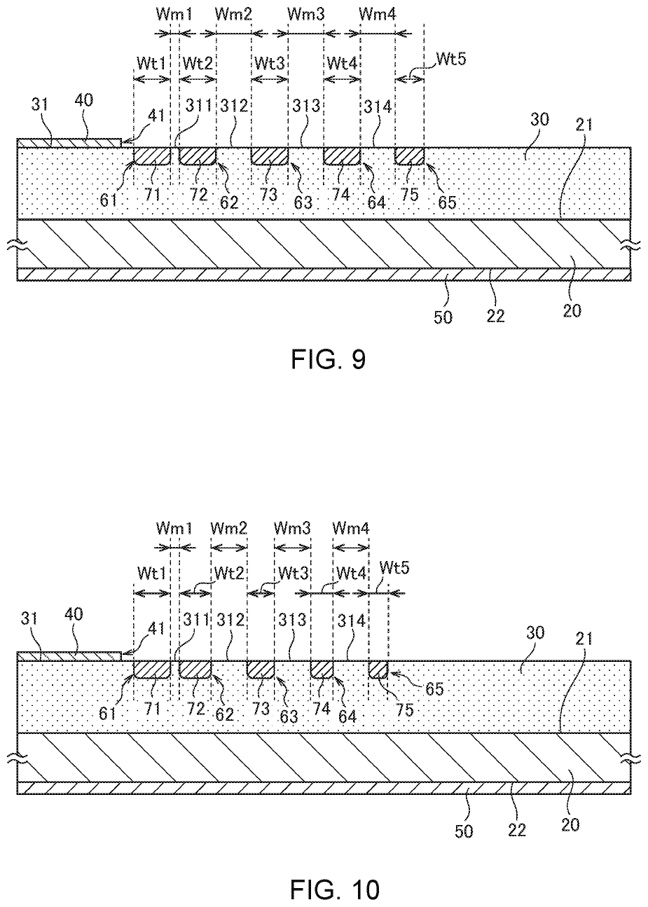

FIG. 9 is a schematic cross-sectional view for explaining the structure of the semiconductor device 2 according to a fourth modification. The fourth modification illustrated in FIG. 9 differs from the semiconductor device 2 illustrated in FIG. 5B in that the relationship Wt1=Wt2=Wt3=Wt4>Wt5 holds. That is, the width of the outer peripheral trench 65 as the outermost trench is smaller than that of the first outer peripheral trench 61. This makes it possible to reduce the chip size while achieving the same effects as those of the semiconductor device 2 illustrated in FIG. 5B. Further, in the example illustrated in FIG. 9, among two outer peripheral trenches that are adjacent to each other, the outer peripheral trench located on the outer peripheral side has a width smaller than that of the outer peripheral trench on the inner peripheral side or has a width equal to that of the outer peripheral trench on the inner peripheral side. That is, among two outer peripheral trenches that are adjacent to each other, the outer peripheral trench located on the outer peripheral side has a width equal to or smaller than that of the outer peripheral trench on the inner peripheral side.

For example, when the thickness of the drift layer 30 is 15 μm, the depths of the outer peripheral trenches 61 to 65 are 2 μm, the p-type semiconductor members 71 to 75 are formed of NiO, the anode electrode 40 is formed of Ni, and the cathode electrode 50 is formed of a laminated Ti/Au film, the maximum electric field strength applied to the drift layer 30 upon application of a reverse voltage of 2000 V is as follows: when Wt1=Wt2=Wt3=Wt4=4 μm, Wt5=3 μm, Wm1=1 μm, and Wm2=Wm3=Wm4=4 μm, the maximum electric field strength is 5.9 MV/cm. That is, in this case, the same effects as those obtained in the semiconductor device 2 illustrated in FIG. 5B, where the relationship when Wt1=Wt2=Wt3=Wt4=Wt5=4 μm holds, can be obtained.

FIG. 10 is a schematic cross-sectional view for explaining the structure of the semiconductor device 2 according to a fifth modification. The fifth modification illustrated in FIG. 10 differs from the semiconductor device 2 illustrated in FIG. 5B in that the relationship Wt1>Wt2>Wt3 >Wt4>Wt5 holds. That is, among two outer peripheral trenches that are adjacent to each other, the outer peripheral trench located on the outer peripheral side has a width smaller than that of the outer peripheral trench on the inner peripheral side. This makes it possible to further reduce the chip size while achieving the same effects as those of the semiconductor device 2 illustrated in FIG. 5B.

For example, when the thickness of the drift layer 30 is 15 μm, the depths of the outer peripheral trenches 61 to 65 are 2 μm, the p-type semiconductor members 71 to 75 are formed of NiO, the anode electrode 40 is formed of Ni, and the cathode electrode 50 is formed of a laminated Ti/Au film, the maximum electric field strength applied to the drift layer 30 upon application of a reverse voltage of 2000 V is as follows: when Wt1=4 μm, Wt2=3.5 μm, Wt3=3 μm, Wt4=2.5 μm, Wt5=2 μm, Wm1=1 μm, and Wm2=Wm3=Wm4=4 μm, the maximum electric field strength is 5.9 MV/cm. That is, in this case, the same effects as those obtained in the semiconductor device 2 illustrated in FIG. 5B, where the relationship when Wt1=Wt2 =Wt3=Wt4=Wt5=4 μm holds, can be obtained.

### Third Embodiment

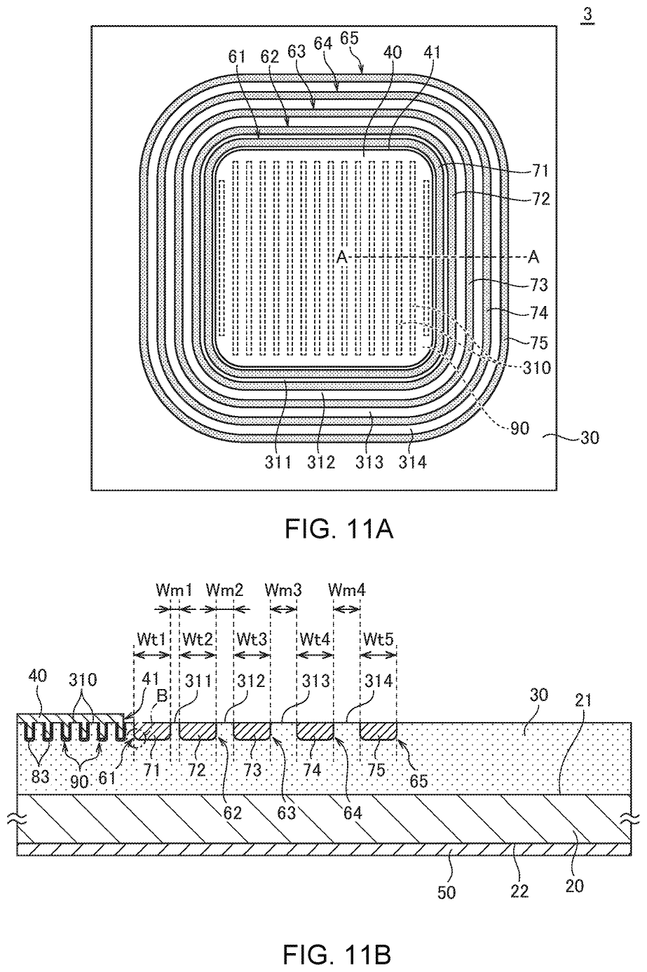

FIG. 11A is a schematic plan view illustrating the configuration of a semiconductor device 3 according to a third embodiment of the technology described herein. FIG. 11B is a schematic cross-sectional view taken along the line A-A in FIG. 11A.

The semiconductor device 3 according to the third embodiment differs from the semiconductor device 2 according to the second embodiment in that a plurality of center trenches 90 are provided in the drift layer 30, and the anode electrode 40 is provided in the center trenches 90 with an insulating film 83 interposed between the anode electrode 40 and the drift layer 30. Other basic configurations are the same as those of the semiconductor device 2 according to the second embodiment, so the same reference numerals are given to the same elements, and overlapping description will be omitted.

The center trenches 90 entirely overlap the anode electrode 40 in a plan view different from the outer peripheral trenches 61 to 65. On the other hand, the outer peripheral trenches 61 to 65 do not overlap the anode electrode 40 at all in a plan view.

The anode electrode 40 provided in the center trenches 90 and the anode electrode 40 provided on the top surface 31 of the drift layer 30 may be formed of the same material or different materials. The depth of the center trenches 90 and the depth of the outer peripheral trenches 61 to 65 may be the same or different. For example, the depth of the center trenches 90 and the depth of the outer peripheral trenches 61 to 65 may be set to about 2 μm.

The portion of the top surface 31 of the drift layer 30 that is located between the two center trenches 90 constitutes a mesa region 310. The mesa region 310 becomes a depletion layer when a reverse voltage is applied between the anode electrode 40 and the cathode electrode 50. As a result, the channel region of the drift layer 30 is pinched off, thereby significantly reducing leakage current upon application of a reverse voltage.

The semiconductor device 3 according to the third embodiment thus includes a plurality of center trenches 90 positioned so as to overlap the anode electrode 40 in a plan view, thereby reducing leakage current. In addition, providing the center trenches 90 also reduces the electric field strength applied to the bottom (denoted by B in FIG. 11B) of the outer peripheral trench 61.

For example, when the thickness of the drift layer 30 is 15 μm, the depths of the outer peripheral trenches 61 to 65 and the center trenches 90 are 2 μm, the p-type semiconductor members 71 to 75 are formed of NiO, the anode electrode 40 is formed of Ni, and the cathode electrode 50 is formed of a laminated Ti/Au film, the maximum electric field strength applied to the bottom (denoted by B) of the outer peripheral trench 61 upon application of a reverse voltage of 2000 V is as follows: when Wt1=Wt2=Wt3=Wt4=Wt5=4 μm, Wm1=1 μm, Wm2=2 μm, and Wm3=Wm4=3 μm, the maximum electric field strength is 4.1 MV/cm in the absence of the center trenches 90 and is reduced to 3.1 MV/cm in the presence of the center trenches 90.

The center trenches 90 illustrated in FIGS. 11A and 11B may be provided in the semiconductor device 1 according to the first embodiment and the semiconductor device 2 according to the second embodiment. That is, in the semiconductor device 1 according to the first embodiment and the semiconductor device 2 according to the second embodiment, the center trenches 90 may be provided in the drift layer 30, and the anode electrode 40 may be provided in the center trenches 90 with the insulating film 83 interposed between the anode electrode 40 and the drift layer 30.

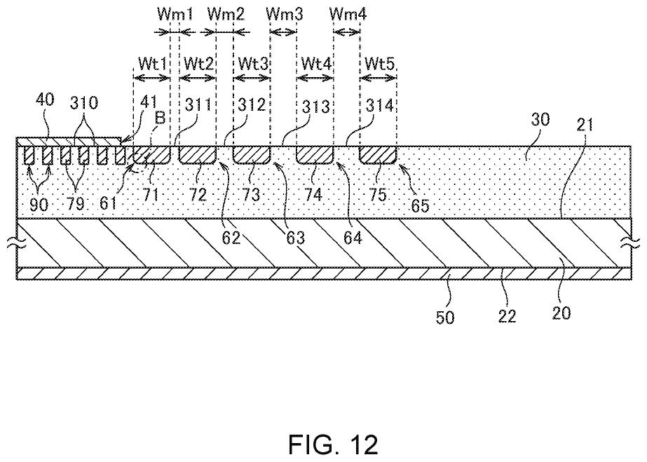

FIG. 12 is a schematic cross-sectional view for explaining the structure of the semiconductor device 3 according to a modification. The modification illustrated in FIG. 12 differs from the semiconductor device 3 illustrated in FIG. 11B in that a p-type semiconductor member 79 having a conductivity type opposite to that of the drift layer 30 is embedded in the center trenches 90. The drift layer 30 and the p-type semiconductor member 79 form a pn junction, thereby achieving a so-called junction barrier Schottky diode. Further, as in the semiconductor device 3, when a reverse voltage is applied between the anode electrode 40 and the cathode electrode 50, the channel region between the mesa regions 310 is pinched off, thereby significantly reducing leakage current upon application of a reverse voltage. In addition, providing the p-type semiconductor member 79 in the center trenches 90 reduces the electric field strength applied to the bottom (denoted by B in FIG. 12) of the outer peripheral trench 61.

For example, when the thickness of the drift layer 30 is 15 μm, the depths of the outer peripheral trenches 61 to 65 and the center trenches 90 are 2 μm, the p-type semiconductor members 71 to 75 and 79 are formed of NiO, the anode electrode 40 is formed of Ni, and the cathode electrode 50 is formed of a laminated Ti/Au film, the maximum electric field strength applied to the bottom (denoted by B) of the outer peripheral trench 61 upon application of a reverse voltage of 2000 V is as follows: when Wt1=Wt2=Wt3=Wt4=Wt5=4 μm, Wm1=1 μm, Wm2=2 μm, and Wm3=Wm4=3 μm, the maximum electric field strength is 4.1 MV/cm in the absence of the center trenches 90 and is reduced to 3.3 MV/cm in the presence of the center trenches 90 in which the p-type semiconductor member 79 is provided.

The center trenches 90 illustrated in FIG. 12 may be provided in the semiconductor device 1 according to the first embodiment and the semiconductor device 2 according to the second embodiment. That is, in the semiconductor device 1 according to the first embodiment and the semiconductor device 2 according to the second embodiment, the center trenches 90 may be provided in the drift layer 30, and the p-type semiconductor member 79 having a conductivity type opposite to that of the drift layer 30 may be provided in the center trenches 90.

While some embodiment of the present disclosure has been described, the technology according to the present disclosure is not limited to the above embodiment, and various modifications may be made within the scope of the present disclosure, and all such modifications are included in the present disclosure.

For example, although the semiconductor substrate 20 and the drift layer 30 are formed of gallium oxide, the material therefor is not limited to this, but may be silicon carbide (SiC), gallium nitride (GaN), aluminum nitride (AlN), diamond (C), silicon (Si), germanium (Ge), silicon germanium (SiGe), gallium arsenide (GaAs), or the like. Even when these material are used as the material for the semiconductor substrate 20 and the drift layer 30, the same effects can be obtained based on the same principle as in the case where gallium oxide is used.

The technology according to the present disclosure includes the following configuration examples but not limited thereto.

A semiconductor device according to an aspect of the present disclosure includes: a semiconductor substrate; a drift layer formed on the semiconductor substrate; a first electrode in contact with the drift layer; and a second electrode in contact with the semiconductor substrate. The drift layer has: a plurality of outer peripheral trenches including a first outer peripheral trench formed so as to surround the first electrode in a plan view without overlapping the first electrode in a plan view and a second outer peripheral trench formed adjacent to the first outer peripheral trench and outside the first outer peripheral trench so as to surround the first outer peripheral trench in a plan view; and a first mesa region located between the first outer peripheral trench and the second outer peripheral trench. The first mesa region has a smaller width than the first outer peripheral trench. With this configuration, the electric field strength applied to the bottom of the first outer peripheral trench is reduced.

In the above semiconductor device, the outer peripheral trenches may further include an outermost peripheral trench located at an outermost periphery, the drift layer may further have a second mesa region located between the outermost peripheral trench and an outer peripheral trench adjacent to the outermost peripheral trench, and the first mesa region may have a smaller width than the second mesa region. This makes the electric field gradient gentler, thereby reducing the maximum electric field applied to the drift layer.

In the above semiconductor device, the drift layer may have a plurality of mesa regions including the first and second mesa regions, and among two mesa regions that are adjacent to each other, the mesa region located on an outer peripheral side may have a width equal to or larger than a width of the mesa region located on an inner peripheral side. With this configuration, the potential difference between two adjacent outer peripheral trenches decreases toward the inner peripheral side, thereby further reducing the maximum electric field applied to the drift layer.

In the above semiconductor device, a width of the second mesa region may be smaller than a width of the outer peripheral trench adjacent to the outermost peripheral trench. This further reduces the maximum electric field applied to the drift layer.

In the above semiconductor device, a width of an outermost peripheral trench included in the outer peripheral trenches may be smaller than a width of the first outer peripheral trench. This makes it possible to reduce the chip size.

In the above semiconductor device, the outer peripheral trenches may include at least three outer peripheral trenches, and among two outer peripheral trenches that are adjacent to each other, the outer peripheral trench located on an outer peripheral side may have a width equal to or smaller than a width of the outer peripheral trench located on an inner peripheral side. This makes it possible to further reduce the chip size.

In the above semiconductor device, the drift layer may further have a plurality of center trenches provided so as to overlap the first electrode in a plan view, and the first electrode may be provided in the center trenches with an insulating film interposed between the first electrode and the drift layer. This makes it possible to reduce leakage current and to reduce the electric field strength applied to the bottom of the first outer peripheral trench.

In the above semiconductor device, the drift layer may further have a plurality of center trenches provided so as to overlap the first electrode in a plan view, and a semiconductor member having a conductivity type opposite to a conductivity type of the drift layer is provided in the center trenches. This makes it possible to reduce leakage current and to reduce the electric field strength applied to the bottom of the first outer peripheral trench.

In the above semiconductor device, the first electrode may be an anode electrode, and the second electrode may be a cathode electrode. This makes it possible to constitute a diode.

In the above semiconductor device, the first electrode may be brought into Schottky contact with the drift layer, and the second electrode may be brought into ohmic contact with the semiconductor substrate. This makes it possible to constitute a Schottky barrier diode.

In the above semiconductor device, a semiconductor member having a conductivity type opposite to a conductivity type of the drift layer may be provided in the outer peripheral trenches, and the semiconductor member provided in the outer peripheral trenches may not be in contact with the first electrode.

What is claimed is:

1. A semiconductor device comprising:
a semiconductor substrate;
a drift layer formed on the semiconductor substrate;
a first electrode in contact with the drift layer; and
a second electrode in contact with the semiconductor substrate,
wherein the drift layer has: a plurality of outer peripheral trenches including a first outer peripheral trench formed so as to surround the first electrode in a plan view without overlapping the first electrode in a plan view and a second outer peripheral trench formed adjacent to the first outer peripheral trench and outside the first outer peripheral trench so as to surround the first outer peripheral trench in a plan view; and a first mesa region located between the first outer peripheral trench and the second outer peripheral trench, and
wherein the first mesa region has a smaller width than the first outer peripheral trench.

2. The semiconductor device as claimed in claim 1,
wherein the outer peripheral trenches further include an outermost peripheral trench located at an outermost periphery,
wherein the drift layer further has a second mesa region located between the outermost peripheral trench and an outer peripheral trench adjacent to the outermost peripheral trench, and
wherein the first mesa region has a smaller width than the second mesa region.

3. The semiconductor device as claimed in claim 2,
wherein the drift layer has a plurality of mesa regions including the first and second mesa regions, and
wherein, among two mesa regions that are adjacent to each other, the mesa region located on an outer peripheral side has a width equal to or larger than a width of the mesa region located on an inner peripheral side.

4. The semiconductor device as claimed in claim 2, wherein a width of the second mesa region is smaller than a width of the outer peripheral trench adjacent to the outermost peripheral trench.

5. The semiconductor device as claimed in claim 1, wherein a width of an outermost peripheral trench included in the outer peripheral trenches is smaller than a width of the first outer peripheral trench.

6. The semiconductor device as claimed in claim 5,
wherein the outer peripheral trenches include at least three outer peripheral trenches, and
wherein, among two outer peripheral trenches that are adjacent to each other, the outer peripheral trench located on an outer peripheral side has a width equal to or smaller than a width of the outer peripheral trench located on an inner peripheral side.

7. The semiconductor device as claimed in claim 1,
wherein the drift layer further has a plurality of center trenches provided so as to overlap the first electrode in a plan view, and
wherein the first electrode is provided in the center trenches with an insulating film interposed between the first electrode and the drift layer.

8. The semiconductor device as claimed in claim 1,
wherein the drift layer further has a plurality of center trenches provided so as to overlap the first electrode in a plan view, and
wherein a semiconductor member having a conductivity type opposite to a conductivity type of the drift layer is provided in the center trenches.

9. The semiconductor device as claimed in claim 1, wherein the first electrode is an anode electrode, and the second electrode is a cathode electrode.

10. The semiconductor device as claimed in claim 9, wherein the first electrode is brought into Schottky contact with the drift layer, and the second electrode is brought into ohmic contact with the semiconductor substrate.

11. The semiconductor device as claimed in claim 1,
wherein a semiconductor member having a conductivity type opposite to a conductivity type of the drift layer is provided in the outer peripheral trenches, and
wherein the semiconductor member provided in the outer peripheral trenches are not in contact with the first electrode.
